(19) United States
(12) Patent Application Publication
(10) Pub. No.: US 2012/0211741 A1
(43) Pub. Date: Aug. 23, 2012

(54) ORGANIC PHOTOVOLTAIC CELL

(76) Inventors: Takehito Kato, Oyama-shi (JP); Toshihiro Ohnishi, Tsukuba-shi (JP)

(21) Appl. No.: 13/503,961

(22) PCT Filed: Oct. 26, 2010
(86) PCT No.: PCT/JP2010/068942

§ 371 Date: Apr. 25, 2012

(30) Foreign Application Priority Data
Oct. 30, 2009 (JP) 2009-250768

(51) Int. Cl. H01L 51/44

(52) U.S. Cl. 257/40; 257/E51.012

(57) ABSTRACT

Provided is an organic photovoltaic cell having high photovoltaic efficiency. The photovoltaic cell of the present invention comprises an anode, a cathode, and an organic active layer provided between the anode and the cathode. The organic active layer comprises a multiexciton generator. For the multiexciton generator, a compound semiconductor comprising one or more elements selected from among Cu, In, Ga, Se, S, Te, Zn and Cd is used. The photovoltaic cell preferably has multiple energy levels in the energy gap of the compound semiconductor. The compound semiconductor is preferably a nanosize particle, and preferably has a p-type semiconductor adhering on the surface thereof.

### TECHNICAL FIELD

The present invention relates to an organic photovoltaic cell used in photovoltaic devices such as solar cells and optical sensors.

### BACKGROUND ART

An organic photovoltaic cell is a cell comprising a pair of electrodes consisting of an anode and a cathode and an organic active layer provided between the pair of electrodes. In an organic photovoltaic cell, one electrode is made of a transparent material. Light is entered from the transparent electrode side and is incident on the organic active layer. The energy (hν) of light incident on the organic active layer generates charges (holes and electrons) in the organic active layer. The generated holes move toward the anode and the electrons move toward the cathode. As a consequence, when an external circuit is connected to the electrodes, current (I) is supplied to the external circuit.

The organic active layer comprises an electron-acceptor compound (n-type semiconductor) and an electron-donor compound (p-type semiconductor). In some cases, the electron-acceptor compound (n-type semiconductor) and the electron-donor compound (p-type semiconductor) are mixed and used to form an organic active layer of single layer structure. In the other cases, an electron-acceptor layer comprising the electron-acceptor compound and an electron-donor layer comprising the electron-donor compound are joined to form an organic active layer of two-layer structure (see, e.g., Patent Document 1).

Usually, the former organic active layer of single layer structure is referred to as a bulk hetero type organic active layer, and the latter organic active layer of two-layer structure is referred to as a heterojunction type organic active layer.

In the former bulk hetero type organic active layer, the electron-acceptor compound and the electron-donor compound form phases of fine and complicated shapes extending continuously from one electrode side to the other electrode side, and form complicated interfaces with being separated from each other. In other words, in the bulk hetero type organic active layer, a phase comprising the electron-acceptor compound and a phase comprising the electron-donor compound are in contact with each other via an interface of an extremely large area. Consequently, an organic photovoltaic cell having the bulk hetero type organic active layer accomplishes a higher photovoltaic efficiency than an organic photovoltaic cell having the heterojunction type organic active layer, in which a layer comprising the electron-acceptor compound and a layer comprising the electron-donor compound are in contact with each other via a single flat interface.

### RELATED ART DOCUMENTS

### Patent Documents

Patent Document 1: JP 2009-084264 A

### SUMMARY OF THE INVENTION

Besides the above mentioned organic photovoltaic cells, there is another type of photovoltaic cell, i.e., an inorganic photovoltaic cell having an active layer made from an inorganic semiconducting material such as crystalline silicon and amorphous silicon. The organic photovoltaic cell has advantages over the inorganic photovoltaic cell in that the organic active layer can be easily manufactured at room temperature by an applying method or the like, and that it is light-weight, for example. The organic photovoltaic cell, however, has a drawback in that its photovoltaic efficiency is low.

There is an overriding imperative for improving photovoltaic efficiency of photovoltaic cells, whether organic or inorganic. Particularly, there is a demand today for improving photovoltaic efficiency of the organic photovoltaic cell having an advantage in terms of manufacture.

The present invention provides an organic photovoltaic cell having high photovoltaic efficiency.

The terms “HOMO” and “LUMO” as used herein are intended to indicate energy states of a molecule of a given substance. “HOMO” stands for highest occupied molecular orbital and means the highest energy state in the ground state energies of a molecule of a given substance. “LUMO” stands for lowest unoccupied molecular orbital and means the lowest energy state in the excited state energies of a molecule of a given substance. When a molecule absorbs light, an electron in HOMO is excited to move to LUMO. In addition, the term “vacuum level” means the lowest energy level of an electron which exists in a molecule of a given substance that is in vacuum and has no kinetic energy. When a molecule of a given substance has a band gap (or is a semiconductor), the vacuum level may be lower than the bottom of the conduction band (nearly equal to LUMO level).

[1] An organic photovoltaic cell comprising:

an anode;

a cathode; and

an organic active layer provided between the anode and the cathode, wherein

the organic active layer comprises a multiexciton generator.

[2] The organic photovoltaic cell according to [1], wherein the multiexciton generator is composed of a compound semiconductor comprising one or more elements selected from among Cu, In, Ga, Se, S, Te, Zn and Cd.

[3] The organic photovoltaic cell according to [2], wherein the organic photovoltaic cell has multiple energy levels in an energy gap of the compound semiconductor.

[4] The organic photovoltaic cell according to any one of [1] to [3], wherein the organic active layer comprises a first p-type semiconductor and an n-type semiconductor.

[5] The organic photovoltaic cell according to any one of [2] to [4], wherein the compound semiconductor is a nanosize particle.

[6] The organic photovoltaic cell according to [5], wherein the first p-type semiconductor adheres to a surface of the compound semiconductor nanoparticle.

[7] The organic photovoltaic cell according to any one of [4] to [6], wherein HOMO level and LUMO level that define an energy gap of the compound semiconductor are within an energy gap between HOMO level and LUMO level of the first p-type semiconductor.

[8] The organic photovoltaic cell according to [5], wherein the organic active layer further comprises a second p-type semiconductor, and the second p-type semiconductor adheres to a surface of the compound semiconductor nanoparticle.

[9] The organic photovoltaic cell according to [8], wherein

an energy gap between HOMO level and LUMO level of the compound semiconductor is smaller than an energy gap between HOMO level and LUMO level of each of the second p-type semiconductor and the n-type semiconductor,

an energy band close to vacuum level of the compound semiconductor is farther from vacuum level of the compound semiconductor than LUMO levels of the second p-type semiconductor and the n-type semiconductor, and

an energy band away from vacuum level of the compound semiconductor is closer to vacuum level of the compound semiconductor than HOMO levels of the second p-type semiconductor and the n-type semiconductor.

[10] The organic photovoltaic cell according to [8], wherein

an energy gap between HOMO level and LUMO level of the compound semiconductor is smaller than an energy gap between HOMO level and LUMO level of each of the first p-type semiconductor, the second p-type semiconductor and the n-type semiconductor,

an energy band close to vacuum level of the compound semiconductor is farther from vacuum level of the compound semiconductor than LUMO levels of the first p-type semiconductor, the second p-type semiconductor and the n-type semiconductor, and

an energy band away from vacuum level of the compound semiconductor is closer to vacuum level of the compound semiconductor than HOMO levels of the first p-type semiconductor, the second p-type semiconductor and the n-type semiconductor.

### EMBODIMENTS FOR CARRYING OUT THE INVENTION

As mentioned above, the organic photovoltaic cell of the present invention comprises an anode, a cathode, and an organic active layer provided between the anode and the cathode, and is characterized in that the organic active layer comprises a multiexciton generator.

With the organic photovoltaic cell of the present invention, the organic active layer comprises a nanoparticle as a multiexciton generator that has a plurality of energy bands. Therefore, excitons (Coulomb-correlated electron-hole pairs) are generated as a result of light absorption by the multiexciton generator as well as light absorption by the organic active layer material, leading to generation of a plurality of electrons and holes. Because of this effect, current generated in the organic photovoltaic cell is increased compared to the case without a multiexciton generator.

The components of the organic photovoltaic cell of the present invention, including an anode, an organic active layer, a multiexciton generator contained in the organic active layer, a cathode, and other components formed as required will be described in detail below.

(Basic Form of the Photovoltaic Cell)

In a basic form of the photovoltaic cell of the present invention, the photovoltaic cell comprises a pair of electrodes, at least one of which is transparent or translucent, and a bulk hetero type organic active layer formed from an organic composition of an electron-donor compound (p-type organic semiconductor) and an electron-donor compound (n-type organic semiconductor, for example). The organic active layer further comprises a multiexciton generator as described below.

(Basic Action of the Photovoltaic Cell)

The energy of light incident from the transparent or translucent electrode is absorbed by the electron-acceptor compound (n-type semiconductor) such as a fullerene derivative and/or the electron-donor compound (p-type semiconductor) such as a conjugated macromolecular compound to generate excitons in which electrons and holes are bonded to each other by coulomb coupling. When the generated excitons move and reach a heterojunction interface where the electron-acceptor compound and the electron-donor compound are adjacent to each other, electrons and holes are separated due to a difference in each of HOMO energy and LOMO energy at the interface to generate charges that can move independently (electrons and holes). Each of the generated charges can be extracted outside as electric energy (current) by moving toward the respective electrode.

(Substrate)

The photovoltaic cell of the present invention is usually formed on a substrate. The substrate may be any substrate as long as it does not undergo chemical change when electrodes and an organic layer are formed. Examples of materials for the substrate may include glass, plastic, macromolecular films, and silicon. When an opaque substrate is used, the opposite electrode (i.e., the electrode located farther from the substrate) is preferably transparent or translucent.

(Electrodes)

Materials for the transparent or translucent electrode may include a conductive metal oxide film and a translucent metal thin film. Specifically, a film made of conductive materials such as indium oxide, zinc oxide, tin oxide, and composites thereof, e.g., indium tin oxide (ITO), indium zinc oxide (IZO) and NESA; gold; platinum; silver; and copper are used. Among these electrode materials, ITO, indium zinc oxide, and tin oxide are preferred. Examples of methods for manufacturing electrodes may include a vacuum deposition method, a sputtering method, an ion plating method, and a plating method. For the electrode materials, organic transparent conductive films such as polyaniline and derivatives thereof, and polythiophene and derivatives thereof may also be used.

The other electrode is not necessarily transparent, and electrode materials such as metals and conductive macromolecules may be used for the electrode. Specific examples of materials for the electrode may include metals such as lithium, sodium, potassium, rubidium, cesium, magnesium, calcium, strontium, barium, aluminum, scandium, vanadium, zinc, yttrium, indium, cerium, samarium, europium, terbium and ytterbium; alloys of two or more of these metals; alloys of one or more of these metals with one or more metals selected from the group consisting of gold, silver, platinum, copper, manganese, titanium, cobalt, nickel, tungsten and tin; graphite; graphite intercalation compounds; polyaniline and derivatives thereof; and polythiophene and derivatives thereof. Examples of the alloys may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

(Intermediate Layer)

Additional intermediate layers (such as charge transport layer) other than the organic photoactive layer may be used as a means of improving photovoltaic efficiency. Materials for the intermediate layers may include halides or oxides of alkali metals or alkaline earth metals such as lithium fluoride. Fine particles of inorganic semiconductors such as titanium oxide, and PEDOT (poly-3,4-ethylenedioxythiophene) may also be used.

(Organic Active Layer)

The organic active layer included in the photovoltaic cell of the present invention comprises an electron-donor compound, an electron-acceptor compound, and a multiexciton generator.

The electron-donor compound, the electron-acceptor compound, and the multiexciton generator are relatively determined on the basis of an energy level of energy levels these compounds. The criterion for such determination will be detailed in the description of the multiexciton generator below.

(Electron-Donor Compound: p-Type Semiconductor)

Examples of the electron-donor compound may include p-type semiconducting polymers such as pyrazoline derivatives, arylamine derivatives, stilbene derivatives, triphenyldiamine derivatives, oligothiophene and derivatives thereof, polyvinyl carbazole and derivatives thereof, polysilane and derivatives thereof, polysiloxane derivatives having an aromatic amine in the side chain or main chain thereof, polyaniline and derivatives thereof, polythiophene and derivatives thereof, polypyrrole and derivatives thereof, polyphenylene vinylene and derivatives thereof, and polythienylene vinylene and derivatives thereof.

In addition, an organic macromolecular compound having a structural unit indicated by the structural formula (1) below may be mentioned as a preferred p-type semiconducting polymer.

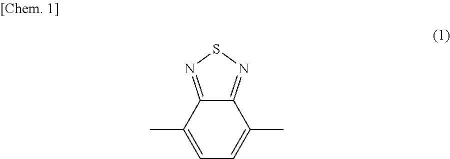

For the organic macromolecular compound, more preferably used is a copolymer of a compound having the structural unit indicated by the structural formula (1) and a compound indicated by the structural formula (2) below:

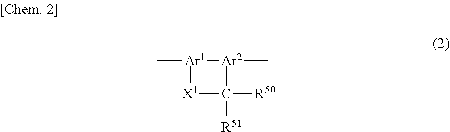

wherein Ar¹ and Ar², which are the same as or different from each other, represent a trivalent heterocyclic group; X¹ represents —O—, —S—, —C(═O)—, —S(═O)—, —SO₂——Si(R³)(R⁴)—, —N(R⁵)—, —B(R⁶)—, —P(R⁷)—, or —P(═O) (R⁸)—; R³, R⁴, R⁵, R⁶, R⁷ and R⁸, which are the same as or different from each other, represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group; R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group or a cyano group; R51 represents an alkyl group having 6 or more carbon atoms, an alkyloxy group having 6 or more carbon atoms, an alkylthio group having 6 or more carbon atoms, an aryl group having 6 or more carbon atoms, an aryloxy group having 6 or more carbon atoms, an arylthio group having 6 or more carbon atoms, an arylalkyl group having 7 or more carbon atoms, an arylalkyloxy group having 7 or more carbon atoms, an arylalkylthio group having 7 or more carbon atoms, an acyl group having 6 or more carbon atoms, or an acyloxy group having 6 or more carbon atoms; and X¹ and Ar² are bonded to vicinal positions on a heterocycle contained in Ar¹, and C(R⁵⁰)(R⁵¹) and Ar¹ are bonded to vicinal positions on a heterocycle contained in Ar².

Specific examples of the copolymers are a macromolecular compound A, which is a copolymer of the two compounds indicated in the structural formula (3) below, and a macromolecular compound B indicated by the structural formula (4).

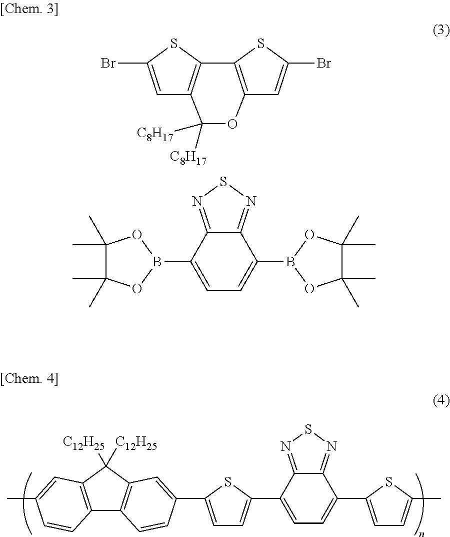

(Electron-Acceptor Compound: n-Type Semiconductor)

Examples of the electron-acceptor compound may include n-type semiconducting polymers such as oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethyelene and derivatives thereof, diphenoquinone derivatives, metal complexes of 8-hydroxyquinoline and of derivatives thereof, polyquinoline and derivatives thereof, polyquinoxaline and derivatives thereof, polyfluorene and derivatives thereof, fullerenes such as C₆₀ and derivatives thereof, and phenanthrene derivatives such as bathocuproine; metal oxides such as titanium oxide; and carbon nanotubes. Preferred electron-acceptor compounds are titanium oxide, carbon nanotubes, fullerene, and fullerene derivatives, and especially preferred electron-acceptor compounds are fullerene and fullerene derivatives.

Examples of the fullerene may include C₆₀ fullerene, C₇₀ fullerene, C₇₆ fullerene, C₇₈ fullerene, and C₆₄ fullerene.

The fullerene derivatives may include C₆₀ fullerene derivatives, C₇₀ fullerene derivatives, C₇₆ fullerene derivatives, C₇₈ fullerene derivatives, and C₈₄ fullerene derivatives. Specific structures of the fullerene derivatives are as follows.

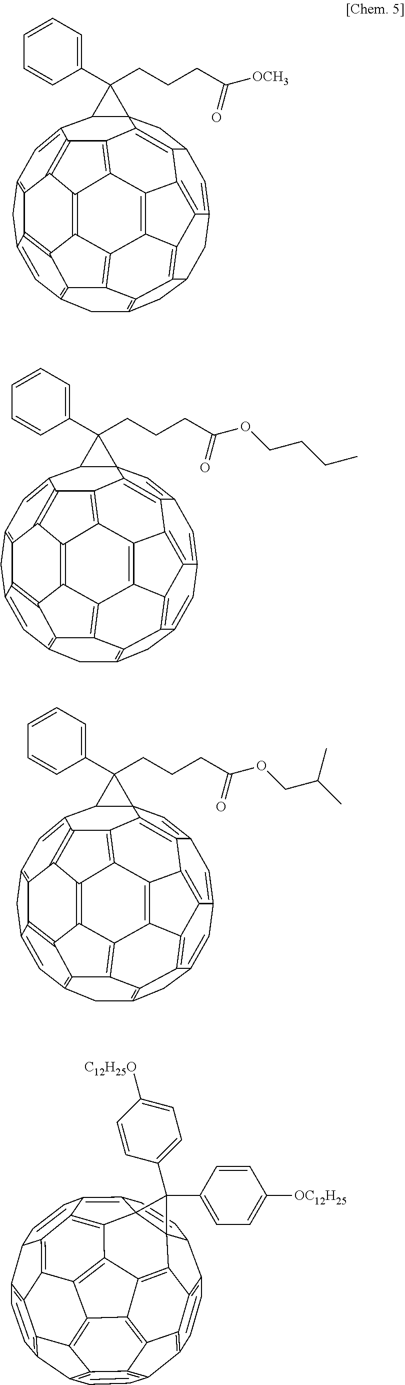

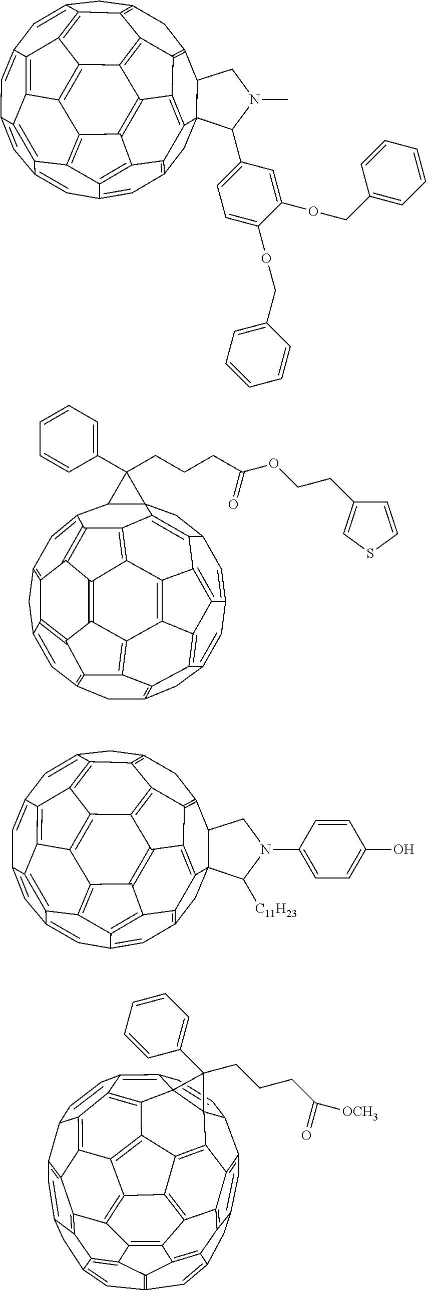

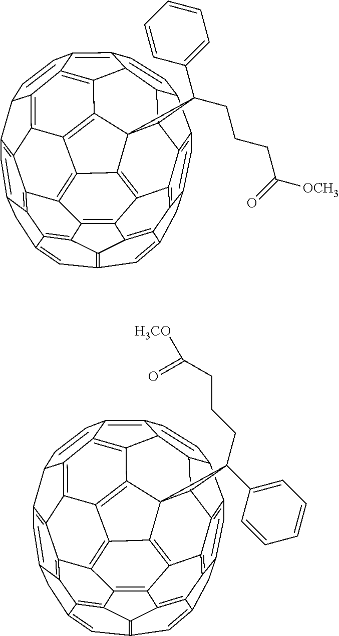

Examples of the fullerene derivatives may include [6,6]-phenyl C61 butyric acid methyl ester (C60PCBM), [6,6]-phenyl C71 butyric acid methyl ester (C70PCBM), [6,6]-phenyl C85 butyric acid methyl ester (C84PCBM), and [6,6]-thienyl C61 butyric acid methyl ester.

When the fullerene derivative is used as the electron-acceptor compound, the fullerene derivative is used preferably in a ratio of from 10 to 1000 parts by weight, more preferably from 20 to 500 parts by weight, per 100 parts by weight of the electron-donor compound.

Usually, the thickness of the organic photoactive layer is preferably from 1 nm to 100 μm, more preferably 2 nm to 1000 nm, further preferably 5 nm to 500 nm, still more preferably 20 nm to 200 nm.

(Multiexciton Generator)

For the multiexciton generator, a compound semiconductor comprising one or more elements selected from among Cu, In, Ga, Se, S, Te, Zn and Cd is used.

Examples of such compound semiconductor may include chalcopyrite compounds comprising Cu, In, Ga, Se and S as a component metal. The chalcopyrite compound may be prepared as follows.

A chalcopyrite compound semiconductor thin film (CIGS thin film) can be formed on a substrate by a vacuum deposition method or a sputtering method. When a vacuum deposition method is employed, each component of the compound (Cu, In, Ga, Se, and S) is individually deposited on a substrate as a vapor source. In a sputtering method, a chalcopyrite compound is used as a target, or each component thereof is individually used as a target.

When a chalcopyrite compound semiconductor thin film is formed on a metal or glass substrate, the substrate is heated to a high temperature, leading to re-evaporation of chalcogens (Se and S). This leaving of chalcogens may cause a compositional change. In such a case, it is desirable to conduct a heat treatment in a vapor atmosphere of Se or S at 400 to 600° C. for one to several hours after film formation to compensate Se or S (selenization or sulfidization).

Next, the compound semiconductor thin film formed on the substrate is mechanically peeled away and ground to nanosize, thus obtaining a chalcopyrite compound semiconductor nonoparticle to be used as the multiexciton generator.

For the compound semiconductor used as the multiexciton generator, a compound semiconductor comprising one type or two or more types of metals selected from among Cu, In, Ga, Se, S, Te, Zn and Cd may also be used. Specific examples thereof may include GaN, CdTe, GaAs, InP, and Gu(In,Ga)Se₂.

In a heterojunction type photovoltaic cell, when the energy of light hν (eV) is between the band gap (forbidden band) Eg1 of a p-type semiconductor (electron-donor compound) and the band gap Eg2 of an n-type semiconductor (electron-acceptor compound), the region where a phase comprising the electron-acceptor compound and a phase comprising the electron-donor compound are in contact is a depletion layer. Electrons generated in the depletion layer move toward the n-type region and holes move toward the p-type region. This develops electromotive force in the organic active layer, allowing current (I) to be supplied to an external circuit.

In a photovoltaic cell in which a nanoparticle having a plurality of energy bands is added, as a multiexciton generator, into the organic active layer comprising the p-type semiconductor and the n-type semiconductor, excitons are generated as a result of light absorption by the multiexciton generator as well as light absorption by the p-type and n-type semiconductors, leading to generation of a plurality of electrons and holes.

Accordingly, when the organic active layer materials, i.e., the p-type semiconductor and the n-type semiconductor are used as an intermediate band, the criterion for selecting a compound semiconductor is as follows: it is desirable that the compound semiconductor is a compound having a wider band gap than the band gaps of the p-type semiconductor and the n-type semiconductor. Specifically, it is desirable that: (i) an energy level close to vacuum level of the compound semiconductor used as the multiexciton generator is closer to vacuum level of the compound semiconductor than LUMO levels of the p-type and n-type semiconductors; and (ii) an energy level away from vacuum level of the compound semiconductor used as the multiexciton generator is closer to vacuum level of the compound semiconductor than HOMO levels of the p-type and n-type semiconductors.

When the multiexciton generator is used as an intermediate band, this criterion does not apply.

The light absorption edge wavelengths and band gaps of the above-mentioned major compound semiconductors are illustrated in Table 1 below.

TABLE 1

| | Light absorption edge | |
|---|---|---|
| | wavelength (nm) | Band gap (eV) |
| GaN | 366 | 3.39 |
| amorphous Si | 700 | 1.77 |
| CdTe | 816 | 1.52 |
| GaAs | 867 | 1.43 |
| InP | 919 | 1.35 |
| Cu(In,Ga)Se₂ | 954 | 1.3 |
| ZnSb | 2480 | 0.5 |
| GaSb | 1653 | 0.75 |
| CdO | 2254 | 0.55 |
| CdSb | 2556 | 0.485 |
| InAs | 3444 | 0.36 |
| InSb | 6888 | 0.18 |
| InTe | 1069 | 1.16 |
| SnSe | 1378 | 0.9 |
| TlSe | 1698 | 0.73 |
| PbS | 3024 | 0.41 |
| PbSe | 4460 | 0.278 |

The macromolecular compound A has a light absorption edge wavelength of 925 nm, a HOMO energy level of 5.01 eV, a LUMO energy level of 3.45 eV, and a band gap of 1.56 eV. The macromolecular compound B has a light absorption edge wavelength of 550 nm, a HOMO energy level of 5.54 eV, a LUMO energy level of 3.6 eV, and a band gap of 1.9 eV. P3HT has a light absorption edge wavelength of 510 nm, a HOMO energy level of 5.1 eV, a LUMO energy level of 2.7 eV, and a band gap of 2.4 eV.

Among those listed above, especially preferred compound semiconductors used for the multiexciton generator in the present invention are ZnSb, GaSb, CdO, CdSb, InAs, InSb, InTe, SnSe, TlSe, PbS, and PbSe.

Band gaps between HOMO levels and LUMO levels of these compound semiconductors are less than 1.30, which is smaller than band gaps between HOMO levels and LUMO levels of the p-type and n-type semiconductors usually used.

In addition, the energy bands close to vacuum levels of these compound semiconductors are farther from vacuum levels of the compound semiconductors than LUMO levels of the p-type and n-type semiconductors usually used, and the energy bands away from vacuum levels of the compound semiconductors are closer to vacuum levels of the compound semiconductors than HOMO levels of the p-type and n-type semiconductors usually used.

(Method for Manufacturing the Organic Active Layer)

The organic photoactive layer of the present invention is of bulk hetero type and may be formed by a film deposition using a solution comprising the p-type semiconductor, the n-type semiconductor, and the multiexciton generator.

A solvent used for the film deposition using a solution is not particularly limited as long as the solvent can dissolve the p-type semiconductor and the n-type semiconductor. Examples of such solvent may include unsaturated hydrocarbon solvents such as toluene, xylene, mesitylene, tetralin, decalin, bicyclohexyl, n-butylbenzene, sec-butylbenzene and tert-butylbenzene; halogenated saturated hydrocarbon solvents such as tetrachlorocarbon, chloroform, dichloromethane, dichloroethane, chlorobutane, bromobutane, chloropentane, bromopentane, chlorohexane, bromohexane, chlorocyclohexane and bromocyclohexane; halogenated unsaturated hydrocarbon solvents such as chlorobenzene, dichlorobenzene and trichlorobenzene; and ether solvents such as tetrahydrofuran and tetrahydropyran. Usually, the polymer of the present invention can be dissolved in the solvent in an amount of 0.1% by weight or more.

For the film deposition, applying methods may be used, such as a spin coating method, a casting method, a micro gravure coating method, a gravure coating method, a bar coating method, a roll coating method, a wire-bar coating method, a dip coating method, a spray coating method, a screen printing method, a gravure printing method, a flexo printing method, an offset printing method, an inkjet printing method, a dispenser printing method, a nozzle coating method, and a capillary coating method. Among these applying methods, a spin coating method, a flexo printing method, a gravure printing method, an inkjet printing method, and a dispenser printing method are preferred.

(Application of Cells)

The photovoltaic cell of the present invention can be operated as an organic thin film solar cell when it is irradiated with light such as sunlight from transparent or translucent electrode to generate a photovoltaic force between the electrodes. It is also possible to use as an organic thin film solar cell module by integrating a plurality of organic thin film solar cells.

It is also possible to operate as an organic optical sensor when a photocurrent flows by irradiation with light from transparent or translucent electrode in a state where a voltage is applied or not applied between the electrodes. It is possible to use an organic image sensor by integrating a plurality of organic optical sensors.

(Solar Cell Module)

The organic thin film solar cell may basically have a module structure similar to that of a conventional solar cell module. The solar cell module usually has a structure in which cells are formed on a supporting substrate, such as metal, and ceramic, and covered with a filler resin, a protective glass or the like, and thus light is captured from the opposite side of the supporting substrate. The solar cell module may also have a structure in which a transparent material such as a reinforced glass is used as the material of a supporting substrate and cells are formed thereon, and thus light is captured from the side of the transparent supporting substrate. Specifically, known examples of the structure of the solar cell module may include module structures such as a superstraight type, a substrate type, and a potting type; and a substrate-integrated module structure used in an amorphous silicon solar cell. The solar cell module using the organic photovoltaic cell of the present invention may appropriately select a suitable module structure depending on an intended purpose, place, environment, and the like.

In a typical superstraight type or substrate type module, cells are arranged at certain intervals between a pair of supporting substrates. One or both of the supporting substrates are transparent and are subjected to antireflection-treatment. The adjacent cells are connected to each other through wiring such as a metal lead and a flexible wiring, and an current collecting electrode is placed at an external peripheral portion of the module for extracting electric power generated in the cell to the exterior. Between the substrate and the cell, various types of plastic materials such as ethylene vinyl acetate (EVA) may be used in the form of a film or a filler resin in order to protect the cell and to improve the electric current collecting efficiency. When the module is used at a place where its surface needs not to be covered with a hard material, for example, at a place unlikely to suffer from impact from outside, one of the supporting substrates can be omitted by forming a surface protective layer with a transparent plastic film or curing the filler resin to impart a protective function. The periphery of the supporting substrate is fixed with a frame made of metal in a sandwich shape so as to seal the inside and to secure rigidity of the module. A space between the supporting substrate and the frame is sealed with a sealing material. A solar cell can also be formed on a curved surface when a flexible material is used for the cell per se, the supporting substrate, the filler material and the sealing material.

In the case of a solar cell with a flexible substrate such as a polymer film, a cell body can be manufactured by sequentially forming cells while feeding a roll-shaped substrate, cutting into a desired size, and then sealing a peripheral portion with a flexible and moisture-resistant material. It is also possible to employ a module structure called “SCAF” described in Solar Energy Materials and Solar Cells, 48, p.383-391. Furthermore, a solar cell with a flexible substrate can also be used in a state of being adhesively bonded to a curved glass or the like.

### EXAMPLES

Examples of the present invention will be illustrated below. The following examples are merely exemplary to illustrate the present invention, and not to intend to limit the present invention.

### Example 1

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by H. C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hotplate at 200° C. for 10 minutes under atmospheric environment, thus forming a hole transport layer on the transparent electrode.

(Preparation of Multiexciton Generator)

Next, a 1% by weight solution of the macromolecular compound A, which is an electron-donor compound represented by the chemical formula (3) below (a first p-type semiconductor), in ortho-dichlorobenzene was prepared.

Into the prepared ortho-dichlorobenzene solution, PbS with an average particle diameter of 10 nm was added at a concentration of 0.5% by weight, and the mixture was stirred to mix and then sonicated for uniform dispersion. The resultant dispersed solution was dried in an N₂ atmosphere to obtain a secondary particle of PbS having the macromolecular compound A coated thereon. The secondary particle of PbS was ground into a particle having an original primary particle size, thus obtaining a multiexciton generator.

The macromolecular compound A, which is a copolymer of two compounds indicated in the structural formula (3) below, had a polystyrene-equivalent weight average molecular weight of 17000 and a polystyrene-equivalent number average molecular weight of 5000. The macromolecular compound A had a light absorption edge wavelength of 925 nm.

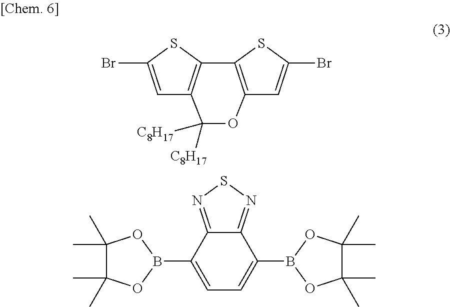

(Formation of Organic Active Layer)

Next, the multiexciton generator (PbS nanoparticle having the first p-type semiconductor on its surface) was added to ortho-dichlorobenzene at a concentration of 0.195% by weight, and stirred and mixed. Thereafter, the mixture was sonicated for dispersion. The dispersion was allowed to stand for a whole day and night, and the supernatant of the solution was collected. The collected supernatant was used to prepare a solution of the macromolecular compound A, which is an electron-donor compound represented by the structural formula (3) above (a first p-type semiconductor), and [6,6]-phenyl C61 butyric acid methyl ester ([6,6]-PCBM), which is an electron-acceptor compound (an n-type semiconductor), in a weight ratio of 1:2. The addition amount of the macromolecular compound A was 0.5% by weight relative to the amount of the solution.

The resultant dispersed solution was applied on the surface of the hole transport layer on the substrate by spin coating and then dried under an N₂ atmosphere. An organic active layer was thus formed on the hole transport layer.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The photovoltaic cell had a shape of square measuring 2 mm by 2 mm.

### Example 2

### Formation of Transparent Substrate-Transparent Anode-Hole Transport Layer

A transparent glass substrate having on its surface a transparent electrode (anode) prepared by sputtering ITO to a film thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISION INC., model “UV-312”).

A suspension of poly(3,4)ethylenedioxythiophene/polystyrene sulfonic acid (manufactured by H. C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hotplate at 200° C. for 10 minutes under atmospheric environment, thus forming a hole transport layer on the transparent electrode.

(Preparation of Multiexciton Generator)

Next, a 1% by weight solution of poly(3-hexylthiophene) (P3HT), which is an electron-donor compound (a first p-type semiconductor), in ortho-dichlorobenzene was prepared.

Into the prepared ortho-dichlorobenzene solution, PbS with an average particle diameter of 10 nm was added at a concentration of 0.5% by weight, and the mixture was stirred to mix and then sonicated for uniform dispersion. The resultant dispersed solution was dried in an N₂ atmosphere to obtain a secondary particle of PbS having poly(3-hexylthiophene) (P3HT) coated thereon. The secondary particle of PbS was ground into a particle having an original primary particle size, thus obtaining a multiexciton generator.

(Formation of Organic Active Layer)

Next, the multiexciton generator (PbS nanoparticle having the first p-type semiconductor on its surface) was added to ortho-dichlorobenzene at a concentration of 0.195% by weight, and stirred and mixed. Thereafter, the mixture was sonicated for dispersion. The dispersion was allowed to stand for a whole day and night, and the supernatant of the solution was collected. The collected supernatant was used to prepare a solution of P3HT, which is an electron-donor compound (a first p-type semiconductor), and [6,6]-phenyl C61 butyric acid methyl ester ([6,6]-PCBM), which is an electron-acceptor compound (an n-type semiconductor), in a weight ratio of 1:0.8. The addition amount of P3HT was 1% by weight relative to the amount of the solution.

The dispersed solution was applied on the surface of the hole transport layer on the substrate by spin coating and then dried under an N₂ atmosphere. An organic active layer was thus formed on the hole transport layer.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The photovoltaic cell had a shape of square measuring 2 mm by 2 mm.

### Example 3

### Formation of Transparent Substrate-Transparent Anode-Hole Transport Layer

A transparent glass substrate having on its surface a transparent electrode (anode) prepared by sputtering ITO to a thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISON INC., model “UV-312”).

A suspension of poly(3,4)ethylenedioxythiophene/polystyrene sulfonic acid (manufactured by H. C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hot plate at 200° C. for 10 minutes under atmospheric environment, thus forming a hole transport layer on the transparent electrode.

(Preparation of Multiexciton Generator)

Next, a 0.5% by weight solution of the macromolecular compound B indicated by the structural formula (4) below, which is an electron-donor compound (a second p-type semiconductor), in ortho-dichlorobenzene was prepared. The macromolecular compound B, which is the second p-type semiconductor, had a light absorption edge wavelength of 550 nm.

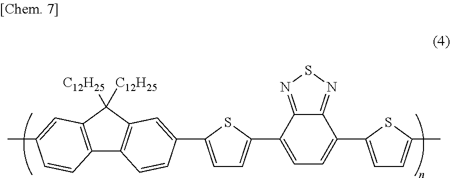

Subsequently, into the prepared ortho-dichlorobenzene solution, PbS with an average particle diameter of 10 nm was added at a concentration of 0.5% by weight, and the mixture was stirred to mix and then sonicated for uniform dispersion. The resultant dispersed solution was dried in an N₂ atmosphere to obtain a secondary particle of PbS having the macromolecular compound B, which is the second p-type semiconductor, coated thereon. The secondary particle of PbS was ground into a particle having an original primary particle size, thus obtaining a multiexciton generator.

(Formation of Organic Active Layer)

Next, the multiexciton generator (PbS nanoparticle having the second p-type semiconductor on its surface) was added to ortho-dichlorobenzene at a concentration of 0.195% by weight, and stirred and mixed. Thereafter, the mixture was sonicated for dispersion. The dispersion was allowed to stand for a whole day and night, and the supernatant of the solution was collected. Into the collected supernatant, the macromolecular compound A which is an electron-donor compound (a first p-type semiconductor), the macromolecular compound B which is a second p-type semiconductor, and [6,6]-phenyl C61 butyric acid methyl ester ([6,6]-PCBM) which is an electron-acceptor compound (an n-type semiconductor) were added in a weight ratio of 2:1:4. The addition amount of the macromolecular compound A was 0.5% by weight relative to the amount of the solution. The resultant solution was applied on the surface of the hole transport layer on the substrate by spin coating and then dried under an N₂ atmosphere. An organic active layer was thus formed on the hole transport layer.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited thereon in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The photovoltaic cell had a shape of square measuring 2 mm by 2 mm.

### Example 4

### Formation of Transparent Substrate-Transparent Anode-Hole Transport Layer

A transparent glass substrate having on its surface a transparent electrode (anode) prepared by sputtering ITO to a thickness of about 150 nm and patterning the ITO was prepared. The glass substrate was washed with an organic solvent, an alkali detergent and ultrapure water, and dried. The dried substrate was subjected to UV-O₃ treatment with a UV ozone apparatus (UV-O₃ apparatus, manufactured by TECHNOVISON INC., model “UV-312”).

A suspension of poly(3,4)ethylenedioxythiophene/polystyrene sulfonic acid (manufactured by H. C. Starck-V TECH Ltd., under the trade name of “Bytron P TP AI 4083”) as a hole transport layer material was prepared and filtrated through a filter having a pore size of 0.5 micron. The filtrated suspension was applied on the transparent electrode side of the substrate by spin coating to form a film in a thickness of 70 nm. The resultant film was dried on a hot plate at 200° C. for 10 minutes under atmospheric environment, thus forming a hole transport layer on the transparent electrode.

(Preparation of Multiexciton Generator)

Next, a 1% by weight solution of the macromolecular compound B, which is an electron-donor compound (a second p-type semiconductor), in ortho-dichlorobenzene was prepared. The macromolecular compound B, which is the second p-type semiconductor, had a light absorption edge wavelength of 550 nm.

Subsequently, into the prepared ortho-dichlorobenzene solution, PbS with an average particle diameter of 10 nm was added at a concentration of 0.5% by weight, and the mixture was stirred to mix and then sonicated for uniform dispersion. The resultant dispersed solution was dried in an N₂ atmosphere to obtain a secondary particle of PbS having the macromolecular compound B, which is the second p-type semiconductor, coated thereon. The secondary particle of PbS was ground into a particle having an original primary particle size, thus obtaining a multiexciton generator.

(Formation of Organic Active Layer)

Next, the multiexciton generator (PbS nanoparticle having the second p-type semiconductor on its surface) was added to ortho-dichlorobenzene at a concentration of 0.195% by weight, and stirred and mixed. Thereafter, the mixture was sonicated for dispersion. The dispersion was allowed to stand for a whole day and night, and the supernatant of the solution was collected. Into the collected supernatant, P3HT which is an electron-donor compound (a first p-type semiconductor), the macromolecular compound B which is a second p-type semiconductor, and [6,6]-phenyl C61 butyric acid methyl ester ([6,6]-PCBM) which is an electron-acceptor compound (an n-type semiconductor) were added in a weight ratio of 2:1:4. The addition amount of the macromolecular compound A was 0.5% by weight relative to the amount of the solution.

The resultant solution was applied on the surface of the hole transport layer on the substrate by spin coating and dried in an N₂ atmosphere. An organic active layer was thus formed on the hole transport layer.

(Formation of Electron Transport Layer-Cathode and Sealing Treatment)

Finally, the substrate was placed in a resistance heating evaporation apparatus. LiF was deposited on the organic active layer in a film thickness of about 2.3 nm to form an electron transport layer, and then Al was deposited in a film thickness of about 70 nm to form a cathode. Thereafter, a sealing treatment was conducted by adhesively bonding a glass substrate to the cathode with using an epoxy resin (fast-setting Araldite) as a sealing material, thus obtaining an organic photovoltaic cell.

The photovoltaic cell had a shape of square measuring 2 mm by 2 mm.

### Comparative Example 1

An organic photovoltaic cell was prepared in the same manner as Example 1 except that the multiexciton generator was not used. In other words, Comparative Example 1 was different from Example 1 in that the organic active layer was prepared without the multiexciton generator as follows.

(Formation of Organic Active Layer)

A solution of the macromolecular compound A represented by the structural formula (3) above, which is an electron-donor compound (a first p-type semiconductor), and [6,6]-phenyl C61 butyric acid methyl ester ([6,6]-PCBM), which is an electron-acceptor compound (an n-type semiconductor), in a weight ratio of 1:2 in ortho-dichlorobenzene was prepared.

The prepared solution was applied on the surface of the hole transport layer on the substrate by spin coating and then dried in an N₂ atmosphere. An organic active layer was thus formed on the hole transport layer.

### Comparative Example 2

An organic photovoltaic cell was prepared in the same manner as Example 2 except that the multiexciton generator was not used. In other words, Comparative Example 2 was different from Example 2 in that the organic active layer was prepared without the multiexciton generator as follows.

(Formation of Organic Active Layer)

A solution of poly(3-hexylthiophene) (P3HT), which is an electron-donor compound (a first p-type semiconductor), and [6,6]-phenyl C61 butyric acid methyl ester ([6,6]-PCBM), which is an electron-acceptor compound (an n-type semiconductor), in a weight ratio of 1:0.8 in ortho-dichlorobenzene was prepared.

The prepared solution was applied on the surface of the hole transport layer on the substrate by spin coating and then dried in an N₂ atmosphere. An organic active layer was thus formed on the hole transport layer.

### Comparative Example 3

An organic photovoltaic cell was prepared in the same manner as Example 3 except that the multiexciton generator was not used. In other words, Comparative Example 3 was different from Example 3 in that the organic active layer was prepared without the multiexciton generator as follows.

(Formation of Organic Active Layer)

A solution of the macromolecular compound A which is an electron-donor compound (a first p-type semiconductor) represented by the structural formula (3) above, the macromolecular compound B which is a second p-type semiconductor, and [6,6]-phenyl C61 butyric acid methyl ester ([6,6]-PCBM) which is an electron-acceptor compound (an n-type semiconductor) in a weight ratio of 2:1:4 in ortho-dichlorobenzene was prepared.

The prepared solution was applied on the surface of the hole transport layer on the substrate by spin coating and then dried in an N₂ atmosphere. An organic active layer was thus formed on the hole transport layer.

### Comparative Example 4

An organic photovoltaic cell was prepared in the same manner as Example 4 except that the multiexciton generator was not used. In other words, Comparative Example 4 was different from Example 4 in that the organic active layer was prepared without the multiexciton generator as follows.

(Formation of Organic Active Layer)

A solution of poly(3-hexylthiophene) (P3HT) which is an electron-donor compound (a first p-type semiconductor), the macromolecular compound B which is a second semiconductor, and [6,6]-phenyl C61 butyric acid methyl ester ([6,6]-PCBM) which is an electron-acceptor compound (an n-type semiconductor) in a weight ratio of 1:0.5:4.5 in ortho-dichlorobenzene was prepared.

The prepared solution was applied on the surface of the hole transport layer on the substrate by spin coating and then dried in an N₂ atmosphere. An organic active layer was thus formed on the hole transport layer.

(Evaluation of Photovoltaic Efficiency of Photovoltaic Cells)

The photovoltaic efficiency of the photovoltaic cells obtained in Examples 1 to 4 and Comparative Examples 1 to 4 was evaluated as follows.

The obtained photovoltaic cell (presumed as an organic thin film solar cell: a shape of square measuring 2 mm by 2 mm) was irradiated with a certain amount of light using a solar simulator (manufactured by BUNKOKEIKI Co., Ltd, under the trade name of “model CEP-2000”, irradiance: 100 mW/cm²) to measure the generated current and voltage. The photovoltaic efficiency (%) and short-circuit current density were calculated from the measurements. The results are shown in Table 2 and Table 3 below.

TABLE 2

| | Example 1 | Example 2 | Example 3 | Example 4 |
|---|---|---|---|---|
| Photovoltaic efficiency | 3.08 | 1.79 | 1.51 | 1.01 |
| (%) | | | | |
| Short-circuit current | 12.01 | 5.49 | 5.5 | 3.47 |
| density (mA/cm²) | | | | |

TABLE 3

| | Comparative | Comparative | Comparative | Comparative |
|---|---|---|---|---|
| | Example 1 | Example 2 | Example 3 | Example 4 |
| Photovoltaic | 3.05 | 1.5 | 1.27 | 0.9 |
| efficiency (%) | | | | |
| Short-circuit | 11.71 | 5.34 | 4.97 | 3.25 |
| current density | | | | |
| (mA/cm²) | | | | |

As can be seen in Table 2 and Table 3, the photovoltaic efficiency and short-circuit current density of each of the photovoltaic cells prepared in Examples 1 to 4 was higher than the photovoltaic efficiency and short-circuit current density of the photovoltaic cell prepared in the corresponding Comparative Examples 1 to 4.

### INDUSTRIAL APPLICABILITY

As described above, the organic photovoltaic cell of the present invention can improve photovoltaic efficiency and is useful in photovoltaic devices such as solar cells and optical sensors, and especially suitable for organic solar cells.

1. An organic photovoltaic cell comprising:
an anode;
a cathode; and
an organic active layer provided between the anode and the cathode, wherein the organic active layer comprises a multiexciton generator.

2. The organic photovoltaic cell according to claim 1, wherein the multiexciton generator is composed of a compound semiconductor comprising one or more elements selected from among Cu, In, Ga, Se, S, Te, Zn and Cd.

3. The organic photovoltaic cell according to claim 2, wherein the organic photovoltaic cell has multiple energy levels in an energy gap of the compound semiconductor.

4. The organic photovoltaic cell according to claim 2, wherein the organic active layer comprises a first p-type semiconductor and an n-type semiconductor.

5. The organic photovoltaic cell according to claim 4, wherein the compound semiconductor is a nanosize particle.

6. The organic photovoltaic cell according to claim 5, wherein the first p-type semiconductor adheres to a surface of the compound semiconductor nanoparticle.

7. The organic photovoltaic cell according to claim 4, wherein HOMO level and LUMO level that define an energy gap of the compound semiconductor are within an energy gap between HOMO level and LUMO level of the first p-type semiconductor.

8. The organic photovoltaic cell according to claim 5, wherein the organic active layer further comprises a second p-type semiconductor, and the second p-type semiconductor adheres to a surface of the compound semiconductor nanoparticle.

9. The organic photovoltaic cell according to claim 8, wherein
an energy gap between HOMO level and LUMO level of the compound semiconductor is smaller than an energy gap between HOMO level and LUMO level of each of the second p-type semiconductor and the n-type semiconductor,
an energy band close to vacuum level of the compound semiconductor is farther from vacuum level of the compound semiconductor than LUMO levels of the second p-type semiconductor and the n-type semiconductor, and
an energy band away from vacuum level of the compound semiconductor is closer to vacuum level of the compound semiconductor than HOMO levels of the second p-type semiconductor and the n-type semiconductor.

10. The organic photovoltaic cell according to claim 8, wherein
an energy gap between HOMO level and LUMO level of the compound semiconductor is smaller than an energy gap between HOMO level and LUMO level of each of the first p-type semiconductor, the second p-type semiconductor and the n-type semiconductor,
an energy band close to vacuum level of the compound semiconductor is farther from vacuum level of the compound semiconductor than LUMO levels of the first p-type semiconductor, the second p-type semiconductor and the n-type semiconductor, and
an energy band away from vacuum level of the compound semiconductor is closer to vacuum level of the compound semiconductor than HOMO levels of the first p-type semiconductor, the second p-type semiconductor and the n-type semiconductor.
